(19) United States
(12) Patent Application Publication
(10) Pub. No.: US 2026/0372181 A1
(43) Pub. Date: Nov. 19, 2026

(54) MAGNETIC FEATURE ALIGNMENT TECHNIQUES FOR SEMICONDUCTOR STACKING

(71) Applicant: Micron Technology, Inc., Boise, ID (US)

(72) Inventors: Owen R. Fay, Meridian, ID (US); Andrew M. Bayless, Boise, ID (US); Brandon P. Wirz, Boise, ID (US); Jeremy E. Minnich, Boise, ID (US)

(21) Appl. No.: 19/659,185

(22) Filed: Apr. 27, 2026

Related U.S. Application Data
(60) Provisional application No. 63/808,513, filed on May 19, 2025.

(51) Int. Cl. H10W 80/00; H10W 46/00; H10W 72/00; H10W 90/00; H10W 90/20; H10W 90/26

(52) U.S. Cl. CPC H10W 80/163; H10W 46/201; H10W 46/301; H10W 72/07178; H10W 72/07183; H10W 72/07188; H10W 90/26; H10W 90/284; H10W 90/792

(57) ABSTRACT

Magnetic feature alignment techniques for semiconductor stacking (and associated systems, devices, and methods) are disclosed herein. In one embodiment, a method for aligning semiconductor devices includes (i) inducing an electrical current in a placement device using magnetic features disposed in or on a first semiconductor device, (ii) capturing measurements of the induced electrical current, and (iii) identifying locations of the magnetic features along the first semiconductor device based at least in part on the captured measurements. The method can further include aligning the first semiconductor device with a second semiconductor device based at least in part on the identified locations of the magnetic features. In some embodiments, the placement device can include electrical pads and at least one galvanometer coupled to the electrical pads to measure the induced electrical currents. In these and other embodiments, the magnetic features can be embedded beneath a surface of the semiconductor devices.

### CROSS-REFERENCE TO RELATED APPLICATIONS

The present application claims priority to U.S. Provisional Patent Application No. 63/808,513, filed May 19, 2025, the disclosure of which is incorporated herein by reference in its entirety.

### TECHNICAL FIELD

The present disclosure relates to semiconductor manufacturing and packaging. For example, several embodiments of the present technology relate to magnetic feature alignment systems and methods that utilize magnetic features embedded within semiconductor wafers, chips, or substrates to precisely align the wafer, chips, or substrates for stacking.

### BACKGROUND

Semiconductor manufacturing processes often involve stacking and aligning multiple wafers or chips to create complex integrated circuits. These processes require precise positioning to ensure proper electrical connections and functionality in the final device. Alignment techniques typically rely on detecting specific features on the surfaces of wafers or chips to guide their positioning relative to each other. The accuracy of these alignment methods can impact the performance, reliability, and yield of the manufactured semiconductor devices.

Temperature fluctuations in the manufacturing environment can affect the accuracy of some alignment techniques. Additionally, the size and placement of alignment features on wafer or chip surfaces may limit the available space for other critical components. As semiconductor devices become more complex and miniaturized, there is an ongoing effort to improve alignment precision while maximizing the usable area on wafers and chips. Addressing these challenges could potentially lead to advancements in semiconductor manufacturing capabilities and device performance.

### BRIEF DESCRIPTION OF FIGURES

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments shown, but are provided for explanation and understanding.

FIG. 1 is a schematic cross-sectional side view of a wafer, chip, or substrate with embedded magnetic features, the wafer, chip, or substrate configured in accordance with various embodiments of the present technology.

FIG. 2 is a schematic cross-sectional side view of an alignment system including (i) a wafer, chip, or substrate and (ii) a placement device, the alignment system configured in accordance with various embodiments of the present technology.

FIG. 3 is a schematic cross-sectional side view of an alignment system for aligning wafers, chips, and/or substrates using magnetic features, the alignment system configured in accordance with various embodiments of the present technology.

FIG. 4 is a schematic cross-sectional side view of another alignment system for aligning wafers, chips, and/or substrates using magnetic features, the alignment system configured in accordance with various embodiments of the present technology.

FIG. 5 is a flow diagram illustrating a method for aligning wafers, chips, and/or substrates in accordance with various embodiments of the present technology.

FIG. 6 illustrates a graph showing low field and high field conditions of embedded magnetic features in a wafer, chip, or substrate configured in accordance with various embodiments of the present technology.

### DETAILED DESCRIPTION

The present technology is generally directed to using magnetic features embedded in wafers, chips, and/or substrates as alignment markers, such as for alignment and/or stacking with other wafers, chips, and/or substrates. For example, a first wafer, chip, or substrate can include one or more magnetic features embedded therein. The first wafer, chip, or substrate can be coupled to a placement device that can be used to capture measurements of a magnetically induced electrical current. Using the placement device, the first wafer, chip, or substrate can be aligned with a second wafer, chip, or substrate that may also include embedded magnetic features. Maximums in electrical current measurements captured by the placement device can correspond to locations of the strongest magnetic fields, which can indicate alignment of (i) the magnetic features embedded within the first wafer, chip, or substrate with (ii) the magnetic features embedded within the second wafer, chip, or substrate. In this manner, the present technology is expected to improve alignment precision (e.g., between two or more wafers, chips, and/or substrates), manufacturing yield, and/or device performance.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein can be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) can be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features can then be oriented “above” the one or more other elements or features. Thus, the exemplary terms “below” and “under” are non-limiting and can encompass both an orientation of above and below. The device or system can additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements can also be present.

### A. Overview

Many wafer alignment systems rely on optical methods to detect features and align wafers or chips during stacking processes. These optical systems often use infrared cameras to view alignment features on the surfaces of wafers or chips. Optical alignment techniques can face challenges related to temperature fluctuations in the wafer environment. As temperatures change, the accuracy of optical measurements can be affected, potentially leading to misalignment issues during the stacking process. Additionally, many optical alignment features typically need to be relatively large in size, often 30 microns or larger, to be detectable by optical systems. This size requirement can limit the available space on wafer or chip surfaces for other critical components. Furthermore, optical alignment features generally need to be visible on the surface of the wafer or chip, which can restrict design flexibility and potentially interfere with other surface structures or components.

Many alignment techniques also struggle with detecting features through multiple layers of stacked wafers or chips. This limitation can make it challenging to align components accurately in complex multi-layer stacks, potentially leading to reduced performance or reliability in the final assembled devices. Moreover, some existing alignment methods can be sensitive to environmental factors beyond temperature, such as vibrations or atmospheric conditions, further complicating the precise positioning required for advanced semiconductor manufacturing processes.

The present technology addresses these and other challenges by utilizing embedded magnetic features for precise wafer, chip, and/or substrate alignment during stacking processes. Instead of relying on optical detection of surface features, several embodiments of the present technology employ a placement device (e.g., a bond head chuck with electrical pads and a galvanometer) to detect magnetic features embedded within wafers, chips, and/or substrates. This approach is expected to allow for accurate alignment even when the features are not visible on the surface, providing greater design flexibility and potentially reducing interference with other surface structures.

In embodiments in which the placement device includes electrical pads and a galvanometer, the electrical pads can be coupled to the galvanometer via electrical leads. Continuing with this example, when the placement device is brought into proximity with embedded magnetic features in a wafer, chip, or substrate, the electrical pads can experience induced electrical currents. This can occur because a magnet can, when brought into close contact with a coil, increase magnetic flux density in the coil and thereby generate an induced electromotive force and current in the coil. In turn, the galvanometer of the placement device can measure the induced currents, allowing the system to (a) detect locations of the embedded magnetic features and (b) use the detected locations to precisely align multiple wafers, chips, and/or substrates. In this manner, the present technology is expected to enable alignment through multiple layers of stacked components, overcoming limitations of optical systems in detecting features through complex multi-layer stacks.

By utilizing embedded magnetic features, the present technology is also expected to allow for more efficient use of wafer, chip, and/or substrate surface area compared to optical alignment systems that utilize larger optical alignment features. Additionally, the magnetic alignment approach of the present technology is expected to be less susceptible to temperature fluctuations and other environmental factors that can affect optical alignment accuracy. In turn, the increased precision and reliability in the alignment processes of the present technology are expected to lead to improved device performance and manufacturing yield, including in applications such as wafer-on-wafer (WoW) stacking, chip-on-wafer (CoW) stacking, chip-on-chip (CoC) stacking, and/or various other applications involving temporary or permanent bonding between (or stacking of) electrical device components.

### B. Selected Embodiments of Magnetic Feature Alignment Techniques, and Associated Systems, Devices, and Methods

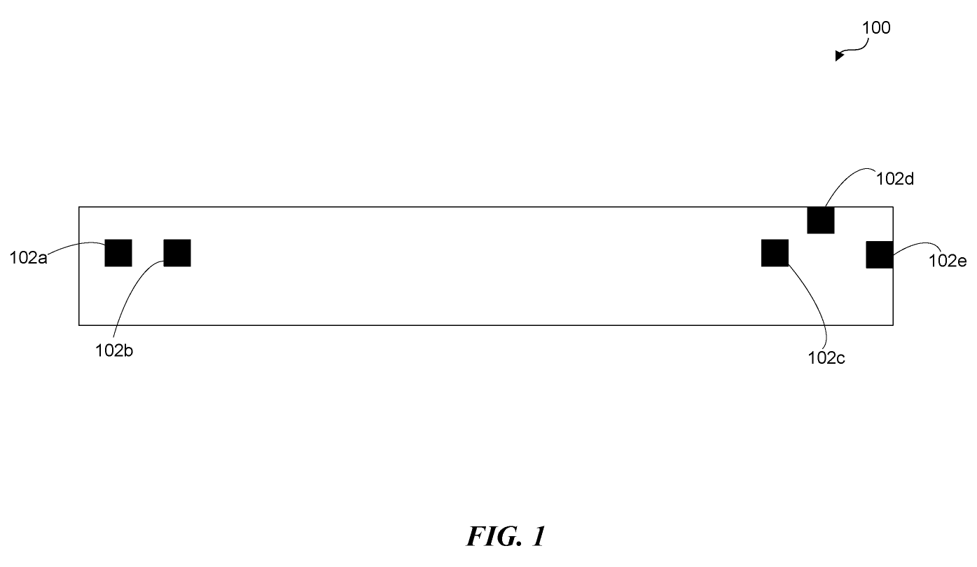

FIG. 1 is a schematic cross-sectional side view of a wafer 100 (or chip or substrate) configured in accordance with various embodiments of the present technology. As shown, the wafer 100 includes a plurality of magnetic features 102 (individually identified in FIG. 1 as first through fifth magnetic features 102a, 102b, 102c, 102d, and 102e) disposed at various locations in, within, on, and/or along the wafer 100. The magnetic features 202 can be made of various materials. For example, the magnetic features can comprise cobalt, NdFeB (Neodymium iron boron), Ferrite (FE3O4), Samarium cobalt (SMCo), magnetic fluids (MF) in stable nano-colloids, and/or another suitable magnetic material. In some embodiments, the size of the magnetic features 102 can be smaller than can be optically detected, such 30 microns or smaller, 15 microns or smaller, or 5 microns or smaller.

In the illustrated embodiment, the magnetic features 102 are embedded beneath a top surface of the wafer 100. More specifically, the magnetic feature 102d is placed at, near, or flush with the top surface of the wafer 100, and the magnetic features 102a, 102b, 102c, and 102e are embedded within the wafer 100 such that the magnetic features 102a, 102b, 102c, and 102e are spaced apart from the top surface of the wafer 100. In addition, the magnetic feature 102e is placed at, near, or flush with an edge of the wafer 100, and the magnetic features 102a, 102b, 102c, and 102e are more centrally located within the wafer 100 such that the magnetic features 102a, 102b, 102c, and 102e are spaced apart from the edges of the wafer 100. In some embodiments, one or more of the magnetic features 102a-102e can be positioned at defined locations, such as in one or more dicing streets and/or within an outline or footprint of one or more dies included in the wafer 100.

In other embodiments, the locations of one or more of the magnetic features 102a-102e can vary from the locations illustrated in FIG. 1. For example, in other embodiments, any one or more of the magnetic features 102a-102e can be positioned at other locations within and/or along wafer 100, including at any location within the wafer 100; at any location on and/or above the top surface of the wafer 100; at any location on, adjacent, and/or along any edge of the wafer 100; and/or at any location on and/or beneath the bottom surface of the wafer 100. Furthermore, the sizes and/or number of the magnetic features 102 used in other embodiments of the present technology can vary from the sizes and/or number, respectively, of the magnetic features 102a-102e shown in FIG. 1. For example, the size of the magnetic features 102 can be larger in other embodiments (e.g., such that they can be optically detected). As another example, one, two, three, four, or more than five magnetic features 102 can be used in other embodiments of the present technology.

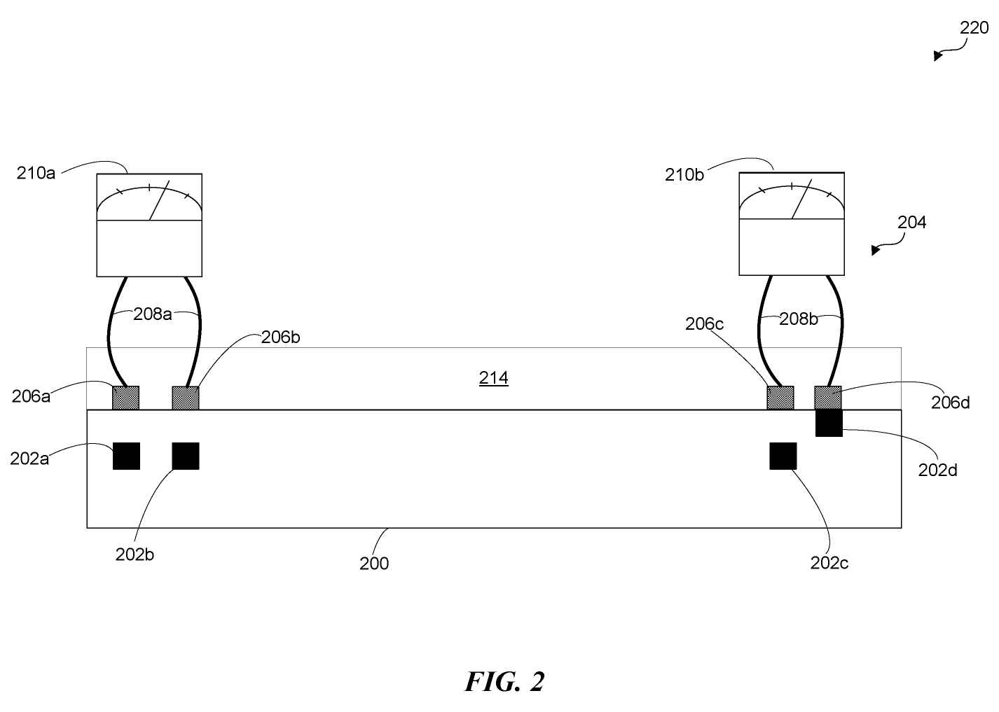

FIG. 2 is a schematic cross-sectional side view of an alignment system 220 configured in accordance with various embodiments of the present technology. As shown, the alignment system 220 includes a wafer 200 (or chip or substrate) and a placement device 204. The wafer 200 is illustrated with a plurality of magnetic features 202 (individually identified in FIG. 2 as first through fourth magnetic features 202a, 202b, 202c, and 202d) positioned at various locations within the wafer 200. The magnetic features 202 can be generally similar (e.g., in composition, location, and/or size) to the magnetic features 102 described above with reference to FIG. 1.

The placement device 204 of FIG. 2 includes a chuck 214, one or more electrical pads 206, and one or more galvanometers 210a and 210b. The placement device 304 can use various mechanisms to manipulate the wafer 200. For example, the chuck 214 can be a vacuum bond head chuck that is usable to pick up, hold, and move the wafer 200. Vacuum-based handling is expected to allow for precise control and positioning of the wafer 200 during an alignment process.

In some embodiments, the electrical pads 206 of the placement device 204 can be formed of copper or another suitable conductive material. In the illustrated embodiment, the electrical pads 206 are each coupled to a corresponding one of the galvanometers 210a and 210b via one or more respective electrical leads 208. For example, the electrical pads 206a and 206b can be coupled as a pair to the galvanometer 210a via electrical leads 208a, and the electrical pads 206c and 206d can be coupled as a pair to the galvanometer 210b via electrical leads 208b. In addition, two or more of the electrical pads 206a-206d can be coupled to one another. For example, the electrical pads 206a and 206b can be coupled to one another, and the electrical pads 206c and 206d can be coupled to one another. In some embodiments, the electrical pads 206a and 206b can be used to form a loop or coil, and the electrical pads 206c and 206d can be used to form a loop or coil.

In operation, through measurements of induced electrical current taken by the galvanometers 210a and 210b, the placement device 204 can be used to (a) detect locations of the magnetic features 202 and/or (b) align the electrical pads 206 with corresponding ones of the magnetic features 202. For example, as the placement device 204 moves relative to the wafer 200 (e.g., laterally in the x-direction and/or y-direction, vertically in the z-direction, and/or rotationally about any one or more of the x-axis, y-axis, and/or z-axis), the magnetic fields of the magnetic features 202a and 202b can induce an electrical current in the electrical pads 206a and 206b as the electrical pads 206a and 206b are brought within the magnetic fields of the magnetic features 202a and 202b. In turn, the galvanometer 210a can detect and measure (via the electrical leads 208a) the electrical current induced in the electrical pads 206a and 206b. The system 220 can use the electrical current measurements taken by the galvanometer 210a to identify or determine the locations of the embedded magnetic features 202a and 202b. For example, locations of the electrical pads 206a and 206b where the highest electrical current values are measured by the galvanometer 210a can indicate the location of the strongest magnetic field, which can indicate the locations of the embedded magnetic features 202a and 202b. In other words, greater electrical current measurements captured by the galvanometer 210a can indicate better alignment of the electrical pads 206a and 206b with the magnetic features 202a and 202b in comparison to lesser electrical current measurements captured by the galvanometer 210a. Thus, assuming the locations of the electrical pads 206a and 206b are known, the electrical current measurements captured by the galvanometer 210a can be used to deduce the locations of the magnetic features 202a and 202b, respectively, within the wafer 200. Additionally, or alternatively, a maximum of electrical current measured by the galvanometer 210a can indicate the position of the chuck 214 at which the electrical pads 206a and 206b are best aligned with the magnetic features 202a and 202b, respectively. The placement device 204 and the galvanometer 210b can be used in a similar way to (a) detect locations of the magnetic features 202c and 202d and/or (b) align the electrical pads 206c and 206d with the magnetic features 202c and 202d, respectively.

Although shown with two galvanometers 210a and 210b, alignment systems configured in accordance with other embodiments of the present technology can include a single (e.g., only one) galvanometer or more than two galvanometers. Additionally, or alternatively, although the galvanometers 210a and 210b are illustrated as being external to the chuck 214, an alignment system configured in accordance with other embodiments of the present technology can include at least one galvanometer that is integrated with a chuck of the alignment system. Furthermore, although shown with four electrical pads 206 in FIG. 2 that are coupled in pairs to a respective one of the galvanometers 210a and 210b, alignment systems configured in accordance with other embodiments of the present technology can include (a) a greater or lesser number of electrical pads, (b) electrical pads positioned at other positions and/or organized in other arrangements than shown in FIG. 2, (c) more than two electrical pads coupled to one another and/or to a same galvanometer, and/or (d) a greater or lesser number of electrical pads than the number of magnetic features embedded within a wafer, chip, or substrate that is manipulated by the placement device.

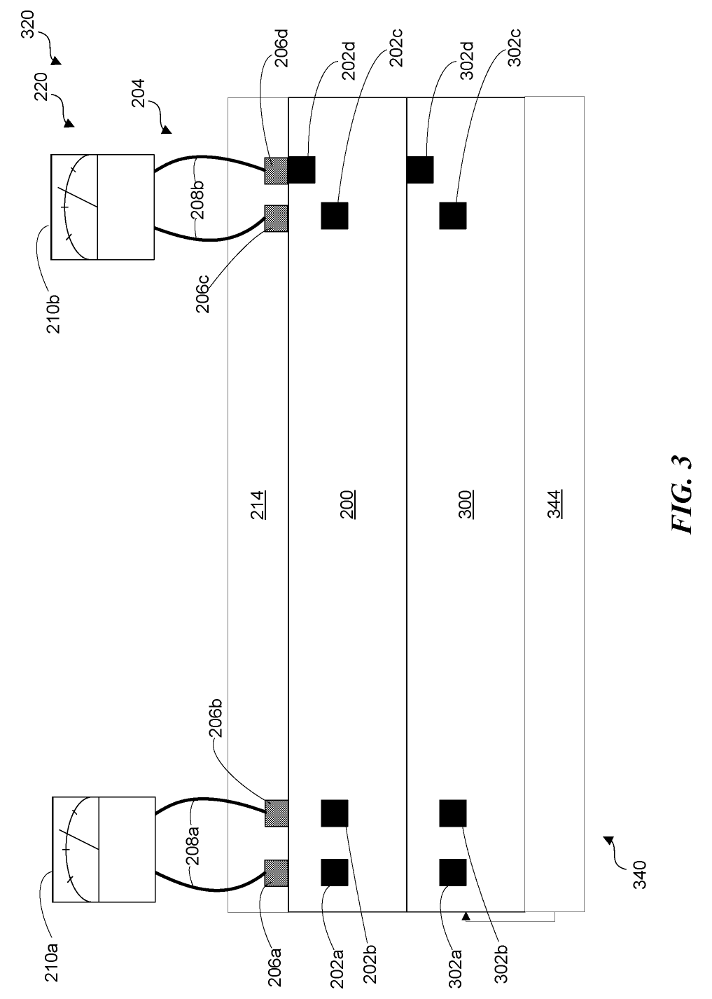

FIG. 3 is a schematic cross-sectional side view of an alignment system 320 configured in accordance with various embodiments of the present technology. As shown, the alignment system 320 includes the alignment system 220 described above with reference to FIG. 2. In addition, the alignment system 320 includes a wafer 300 (or chip or substrate) and a placement device 340 having a chuck 344. In the illustrated embodiment, the wafer 300 can be identical or at least generally similar to the wafer 200. For example, the wafer 300 can include a plurality of magnetic features 302 (individually identified in FIG. 3 as first through fourth magnetic features 302a, 302b, 302c, and 302d) positioned at various locations within the wafer 300. The magnetic features 302 can be identical or at least generally similar (e.g., in composition, location, and/or size) to the magnetic features 102 and/or 202 described above with reference to FIGS. 1 and/or 2. The chuck 344 of the placement device 340 can operate similarly to the chuck 214 and/or can be used to hold and/or manipulate the wafer 300, such as during an alignment process.

Similar to the process described above with reference to FIG. 2, through measurements of electrical current taken by the galvanometers 210a and 210b, the placement device 204 can be used to (a) detect locations of the magnetic features 302 in the wafer 300 and/or (b) align the electrical pads 206 and/or the magnetic features 202 with corresponding ones of the magnetic features 302. For example, as the placement device 204 (i) holds the wafer 200 and (ii) moves the wafer 200 and the chuck 214 relative to the wafer 300 (e.g., laterally in the x-direction and/or y-direction, vertically in the z-direction, and/or rotationally about any one or more of the x-axis, y-axis, and/or z-axis), the magnetic fields of the magnetic features 302a and 302b can induce an electrical current in the electrical pads 206a and 206b when the electrical pads 206a and 206b are brought within the magnetic fields of the magnetic features 302a and 302b. In turn, the galvanometer 210a can detect and measure (e.g., through the wafer 200 and/or the magnetic features 202a and/or 202b) the electrical current induced in the electrical pads 206a and 206b. The system 320 and/or the system 220 can use the electrical current measurements taken by the galvanometer 210a to identify or determine the locations of the embedded magnetic features 302a and 302b. For example, while moving the chuck 214 and/or the wafer 200 relative to the wafer 300, locations of the electrical pads 206a and 206b where the highest electrical current values are measured by the galvanometer 210a can indicate the location of the strongest magnetic field, which can indicate the locations of the embedded magnetic features 302a and 302b. In other words, greater electrical current measurements captured by the galvanometer 210a can indicate better alignment of the electrical pads 206a and 206b with the magnetic features 302a and 302b in comparison to lesser electrical current measurements captured by the galvanometer 210a. And, assuming that the electrical pads 206a and 206b are aligned with the magnetic features 202a and 202b, respectively, per the process described above with reference to FIG. 2, greater electrical current measurements captured by the galvanometer 210a can indicate better alignment of the magnetic features 202a and 202b within the wafer 200 with the magnetic features 302a and 302b, respectively, within the wafer 300 in comparison to lesser electrical current measurements captured by the galvanometer 210a. Thus, assuming the locations of the electrical pads 206a and 206b are known, the electrical current measurements captured by the galvanometer 210a can be used to deduce the locations of the magnetic features 302a and 302b, respectively, within the wafer 300.

Additionally, or alternatively, a maximum of electrical current measured by the galvanometer 210a can indicate the position of the chuck 214 at which the electrical pads 206a and 206b are best aligned with the magnetic features 302a and 302b, respectively. And, assuming that the electrical pads 206a and 206b are aligned with the magnetic features 202a and 202b, respectively, per the process described above with reference to FIG. 2, a maximum of electrical current measured by the galvanometer 210a can indicate the position of the wafer 200 at which the magnetic features 202a and 202b are best aligned with the magnetic features 302a and 302b, respectively. For example, it is expected that when the magnetic feature 202a is aligned with the magnetic feature 302a, the magnetic fields generated by the magnetic features 202a and 302a are aligned and will therefore induce a greatest amount of electrical current in the electrical pad 206a (e.g., when the electrical pad 206a is also aligned with the magnetic features 202a and 302a). The placement device 204 and the galvanometer 210b can be used in a similar way to (a) detect locations of the magnetic features 302c and 302d, (b) align the electrical pads 206c and 206d with the magnetic features 302c and 302d, respectively, and/or (c) align the magnetic features 202c and 202d with the magnetic features 302c and 302d, respectively. The system 320 is therefore expected to enable alignment of the wafer 200 with the wafer 300 by detecting the positions of the magnetic features 202 and 302 using electrical current measurements captured via the galvanometers 210a and 210b.

The alignment system 320 can be capable of detecting embedded features through multiple wafers, dies, and/or substrates. For example, the placement device 204 can detect the magnetic features 302a-302d in the wafer 300 through the wafer 200 and/or the magnetic features 202a-202d. This capability can allow for alignment of complex multi-layer stacks, potentially improving the accuracy and reliability of advanced semiconductor packaging processes. In some embodiments, the alignment system 320 can include monitoring electrical current measurements captured by the galvanometers 210a and 210b to keep the wafers 200 and 300 aligned during bonding. For example, as the wafers 200 and 300 are brought together to be bonded, the electrical current measurements can be continuously monitored to maintain alignment according to the detected magnetic features. This continuous monitoring can allow for real-time adjustments to ensure precise alignment throughout the bonding process, potentially improving the yield and reliability of the final assembled devices.

In the illustrated embodiment, the wafer 300 includes a same number and arrangement of magnetic features 302 as the number and arrangement of magnetic features 202 included within the wafer 200. In other embodiments, a second wafer can include a different number and/or arrangement of magnetic features from the number and/or arrangement of magnetic features included within a first wafer aligned and/or stacked therewith.

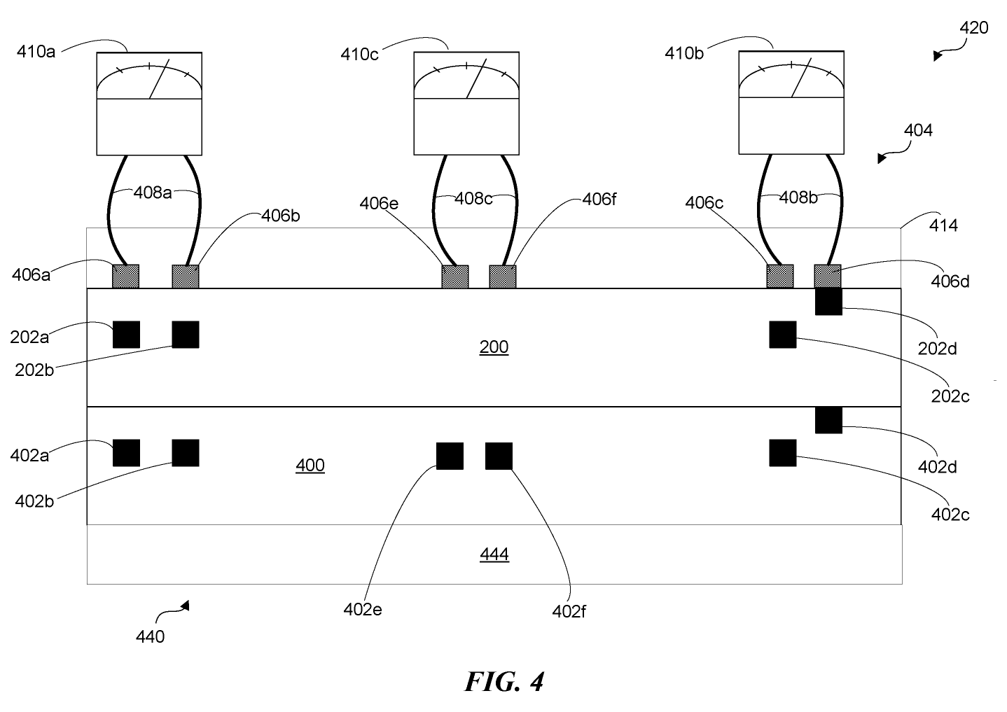

For example, FIG. 4 is a schematic cross-sectional side view of another alignment system 420 configured in accordance with various embodiments of the present technology. The alignment system 420 is generally similar to the alignment systems 220 and 320 described above with reference to FIGS. 2 and 3. Thus, similar reference numbers are used across FIGS. 2-4 to denote identical or at least generally similar components, and a detailed description of these components is largely omitted here for the sake of brevity in light of the detailed description provided above with reference to FIGS. 2 and 3.

In comparison to the alignment systems 220 and 320 of FIGS. 2 and 3, the alignment system 420 of FIG. 4 includes a placement device 404 having (i) a chuck 414 that includes additional electrical pads 406e and 406f and (ii) a third galvanometer 410c. The electrical pads 406e and 406f can be identical or at least generally similar (e.g., in size, composition, and/or arrangement) to the electrical pads 206a-206d of FIGS. 2 and 3 and/or the other electrical pads 406a-406d of the placement device 404. The electrical pads 406e and 406f can be coupled as a pair to the galvanometer 410c via electrical leads 408c. Additionally, or alternatively, the electrical pads 406e and 406f can be coupled to one another and/or used to form a loop or coil.

Furthermore, in comparison to the wafer 300 of FIG. 3, the wafer 400 (or chip or substrate) of FIG. 4 includes magnetic features 402e and 402f. The magnetic features 402e and 402f can be identical or at least generally similar (e.g., in size, composition, and/or arrangement) to the magnetic features 202a-202d of FIGS. 2-4, the magnetic features 302a-302d of FIG. 3, and/or the other magnetic features 402a-402d of FIG. 4. As shown, the magnetic features 402e and 402f are positioned at locations within the wafer 400 that do not align with any of the magnetic features 202 included within the wafer 200. For example, the magnetic features 402e and 402f are positioned within the wafer 400 at generally central locations that are not aligned with any of the magnetic features 202a-202d within the wafer 200 but can be aligned with the electrical pads 406e and 406f, respectively, of the placement device 404.

In operation, the placement device 404 operates generally similar to the placement device 204 of FIGS. 2 and 3. For example, through measurements of electrical current taken by the galvanometers 410a-410c, the placement device 404 can be used to (a) detect locations of the magnetic features 202 in the wafer 200 and/or magnetic features 402 in the wafer 400, (b) align the electrical pads 406 with corresponding ones of the magnetic features 202, and/or (c) align the electrical pads 406 and/or the magnetic features 202 with corresponding ones of the magnetic features 402. As a specific example, as the placement device 404 moves relative to the wafer 400 (e.g., laterally in the x-direction and/or y-direction, vertically in the z-direction, and/or rotationally about any one or more of the x-axis, y-axis, and/or z-axis), the magnetic fields of the magnetic features 402e and 402f can induce an electrical current in the electrical pads 406e and 406f as the electrical pads 406e and 406f are brought within the magnetic fields of the magnetic features 402e and 402f. In turn, the galvanometer 410c can detect and measure (via the electrical leads 408c and/or through the wafer 200) the electrical current induced in the electrical pads 406e and 406f. The system 420 can use the electrical current measurements taken by the galvanometer 410c to identify or determine the locations of the embedded magnetic features 402e and 402f. For example, locations of the electrical pads 406e and 406f where the highest electrical current values are measured by the galvanometer 410c can indicate the location of the strongest magnetic field, which can indicate the locations of the embedded magnetic features 402e and 402f. In other words, greater electrical current measurements captured by the galvanometer 410c can indicate better alignment of the electrical pads 406e and 406f with the magnetic features 402e and 402f in comparison to lesser electrical current measurements captured by the galvanometer 410c. Thus, assuming the locations of the electrical pads 406e and 406f are known, the electrical current measurements captured by the galvanometer 410c can be used to deduce the locations of the magnetic features 402e and 402f, respectively, within the wafer 400. Additionally, or alternatively, a maximum of electrical current measured by the galvanometer 410c can indicate the position of the chuck 414 and/or the wafer 200 at which the electrical pads 406e and 406f are best aligned with the magnetic features 402e and 402f, respectively.

Because the magnetic features 402e and 402f have different locations or arrangements within the wafer in comparison to any of the magnetic features 202 in the wafer 200, electrical current measurements captured by the galvanometer 410c are expected to correspond to the magnetic features 402e and 402f instead of any of the magnetic features 202 in the wafer 200. Stated another way, because the wafer 200 lacks any magnetic features 202 positioned between (i) the electrical pads 406e and 406f and (ii) the magnetic features 402e and 402f, respectively, in the wafer 400, electrical current measurements captured by the galvanometer 410c are expected to correspond primarily to current induced by the magnetic fields of the magnetic features 402e and 402f through the wafer 200. Thus, the magnetic features 202 within the wafer 200 are not expected to interfere with or largely contribute to electrical current measurements captured by the galvanometer 410c, which may enable more precise alignment between the wafer 200 and the wafer 400. The difference in magnetic feature placement within the wafer 400 in comparison to the magnetic feature placement within the wafer 200 is therefore expected to facilitate more flexible and/or precise alignment strategies that may require identification and/or use of magnetic features positioned within wafers located farther from the placement device 404 (e.g., without interference from magnetic features positioned within wafers located closer to the placement device 404).

In some embodiments, non-uniform alignment patterns of magnetic features across two or more wafers, chips, and/or substrates can facilitate focusing on positioning and/or aligning processes for specific layers. As a specific example, the magnetic features 402a-402d of the wafer can be omitted. Continuing with this example, using electrical current measurements of the galvanometers 410a and 410b, the placement device 404 can align the electrical pads 406a-406d with the magnetic features 202a-202d, respectively, within the wafer 200 in accordance with the description provided above with reference to FIG. 2. Thereafter, using electrical current measurements of the galvanometer 410c, the placement device 404 can align the electrical pads 406e and 406f with the magnetic features 402e and 402f, respectively, within the wafer 400. In some embodiments, alignment systems configured in accordance with various embodiments of the present technology can be programmed to recognize and/or utilize the different magnetic feature arrangements across multiple wafers, chips, and/or substrates, and adjust an alignment algorithm accordingly to achieve optimal alignment between the multiple wafers, chips, and/or substrates.

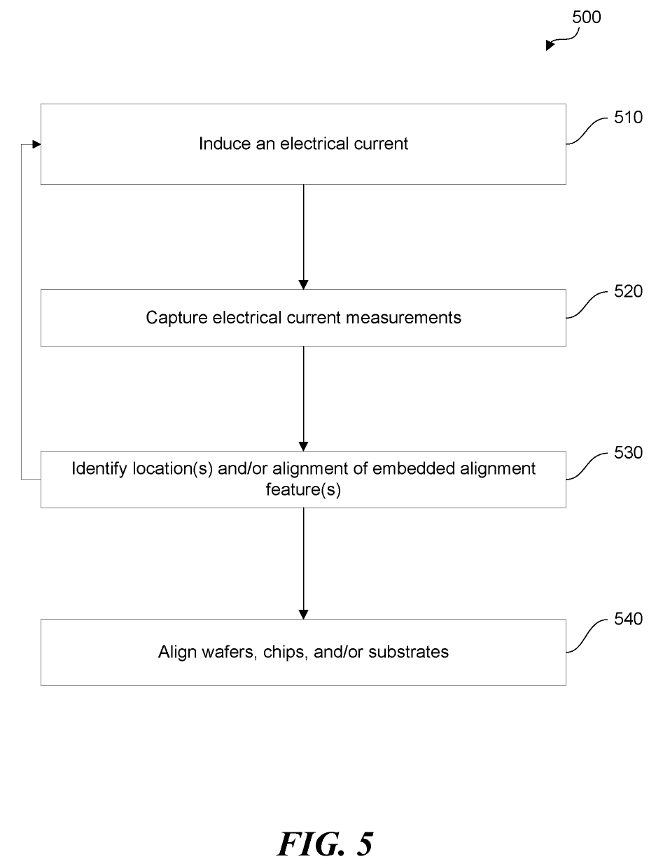

FIG. 5 is a flowchart of a method 500 for aligning wafers, chips, and/or substrates in accordance with various embodiments of the present technology. The method 500 is illustrated as a series of steps 510, 520, 530, and 540. All or a subset of one or more of the steps 510, 520, 530, and 540 can be executed in accordance with the description above and/or with the description that follows.

The method 500 begins at step 510 by inducing an electrical current in a placement device of an alignment system using magnetic features embedded within semiconductor device (e.g., a wafer, chip, and/or substrate). For example, magnetic fields produced by the embedded magnetic features can induce electrical currents in electrical pads of the placement device. The induced currents can form the basis for detecting the presence (e.g., proximity) and/or location of the magnetic features embedded within the semiconductor device. Inducing the electrical current in the placement device can include moving (e.g., a chuck and/or electrical pads) of the placement device relative to the semiconductor device, such as over and/or along a surface of the semiconductor device and/or using a controller or processor of the alignment system.

At step 520, the method 500 continues by capturing measurements of the electrical current induced at step 510. For example, a galvanometer can be coupled to the electrical pads of the placement device and can be used to obtain measurements of the electrical current as the electrical pads of the placement device are moved along and/or relative to the semiconductor device.

At step 530, the method 500 continues by identifying (a) locations of the magnetic features within the semiconductor device, and/or (b) alignment of the magnetic features to the electrical pads of the placement device. As discussed in greater detail above, electrical current measurements captured at step 520 can be used to detect location and/or proximity of the magnetic features embedded within the semiconductor device. For example, the strength and pattern of the electrical current measurements can indicate the presence and position of embedded magnetic features relative to the electrical pads of the placement device. The locations of the magnetic features can be determined based on where the greatest electrical current measurements are detected. For example, as the placement device moves relative to the semiconductor device, electrical currents induced in the electrical pads of the placement device can vary in intensity depending on their proximity to the magnetic features. The greatest current measurements can therefore correspond to locations directly above or nearest to the embedded magnetic features, as the magnetic field strength is typically strongest at these points. Thus, step 530 can include analyzing and identifying (e.g., using a controller or processor) maximums in the electrical current measurements captured at step 520. Step 530 of the method is therefore expected to allow for precise mapping of the magnetic features within the semiconductor device. As shown in FIG. 5, the method 500 can iteratively return to step 510 (or step 520) to determine the location of one or more other embedded magnetic features within the semiconductor device, or within a secondary semiconductor device (e.g., a secondary wafer, chip, or substrate) to be aligned or stacked with the semiconductor device.

At step 540, the method 500 continues by aligning two or more semiconductor devices based on (a) the electrical current measurements captured at step 520 and/or (b) the locations and/or alignment of the embedded magnetic features identified and/or achieved at step 530. In some embodiments, step 540 can include bonding two or more semiconductor devices together. In at least some of these embodiments, step 540 can include monitoring (e.g., using a controller or processor of the alignment system) electrical current measurements captured by the galvanometer(s) of the placement device to keep the two or more semiconductor devices aligned during the bonding. For example, as the two or more semiconductor devices are brought together to be bonded, the electrical current measurements can be continuously monitored to maintain alignment according to the detected magnetic features. This continuous monitoring can allow for real-time adjustments to ensure precise alignment throughout the bonding process, potentially improving the yield and reliability of the final assembled devices. Step 540 is therefore expected to enable precise positioning of semiconductor devices relative to each other based on the detected magnetic features.

Although the steps 510, 520, 530, and 540 of the method 500 are discussed and illustrated in a particular order, the method 500 is not so limited. In other embodiments, all or a subset of one or more of the steps 510, 520, 530, and 540 of the method 500 can be performed in a different order. In these and other embodiments, all or a subset of any of the steps 510, 520, 530, and 540 of the method 500 can be performed before, during, and/or after all or a subset of any of the other steps 510, 520, 530, and 540 of the method 500. Furthermore, a person skilled in the art will readily recognize that the method 500 can be altered and still remain within these and other embodiments of the present technology. For example, all or a subset of one or more steps 510, 520, 530, and 540 of the method 500 can be omitted and/or repeated in some embodiments.

The method 500 of FIG. 5 can be used for various applications in semiconductor manufacturing and packaging. For example, the method 500 (and the description of the present technology provided herein) is not limited to wafer-on-wafer (WoW) processes and is equally applicable to chip-on-wafer (CoW) process, chip-on-chip (CoC) processes, and/or various other applications involving temporary or permanent bonding between two or more electrical device components.

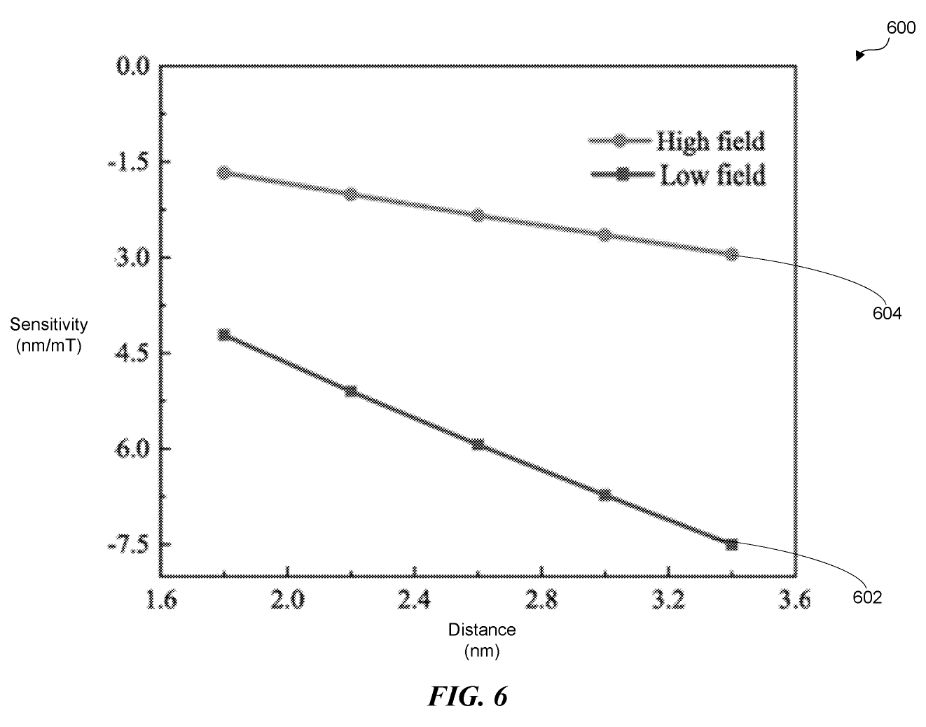

FIG. 6 illustrates a sensitivity graph showing low field and high field conditions of embedded magnetic features in a wafer, chip, or substrate configured in accordance with various embodiments of the present technology. The sensitivity graph 600 displays a first curve 602 representing low field measurements and second curve 604 representing high field measurements. The vertical axis of the sensitivity graph 600 shows sensitivity values in units of nanometer per millitesla (nm/mT), while the horizontal axis shows distance in nanometers (nm). The sensitivity values in the sensitivity graph 600 range from approximately -7.5 to 0 nm/mT, with measurements taken at distance intervals between 1.6 nm and 3.6 nm.

The sensitivity graph 600 demonstrates example accuracy and sensitivity of the magnetic feature detection methods used in the alignment processes described above. In some cases, the sensitivity graph 600 illustrates the relationship between the strength of the detected magnetic field and the distance from the magnetic features embedded in wafers, chips, and/or substrates, such as the wafers 100, 200, 300, and/or 400 of FIGS. 1-4.

The curve 602 of low field measurements in the sensitivity graph 600 can correspond to weaker magnetic fields generated by smaller or more deeply embedded magnetic features. In contrast, the curve 604 of high field measurements can correspond to stronger magnetic fields generated by larger or more superficial magnetic features. The sensitivity graph 600 can indicate that placement devices, such as the placement devices 204 and 404 of FIGS. 2-4, can detect variations in magnetic field strength over very small distances, potentially as small as 0.1 nm. This high level of sensitivity can allow for precise detection and localization of magnetic features within the wafers, enabling accurate alignment during stacking processes.

In some cases, the sensitivity graph 600 can be used to calibrate the alignment systems 220, 320, and/or 420 of FIGS. 2-4. For example, by understanding the relationship between field strength and distance as shown in the sensitivity graph 600, the systems can more accurately interpret the electrical current measurements obtained by the galvanometers. The sensitivity graph 600 can also illustrate the potential for detecting magnetic features through multiple layers of stacked wafers, chips, and/or substrates. The graph shows measurable differences in sensitivity even at distances approaching 3.6 nm, suggesting that the alignment systems can be capable of detecting magnetic features embedded deep within a stack of wafers, chips, and/or substrates. Furthermore, the sensitivity graph 600 can demonstrate the robustness of the magnetic feature detection method across different field strengths. The consistent trend in both low and high field measurements suggests that the method can be effective for a range of magnetic feature sizes and compositions, potentially allowing for flexibility in the design and placement of magnetic features within the wafers, chips, and/or substrates.

In some cases, the data represented in the sensitivity graph 600 can be used to optimize the placement and design of magnetic features within the wafers, chips, and/or substrates. By understanding the relationship between field strength and detection sensitivity, engineers can design magnetic features that provide optimal signal strength while minimizing their size, potentially allowing for more efficient use of space within or on wafers, chips, and/or substrates. The sensitivity graph 600 can also provide insights into the potential accuracy of the alignment process. The small-scale variations in sensitivity shown in the graph suggest that the alignment systems can be capable of detecting and responding to very small changes in the position of magnetic features, potentially enabling nanometer-scale alignment precision.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments can perform steps in a different order. Furthermore, the various embodiments described herein can also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology.

Where the context permits, singular or plural terms can also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” can be based on both condition A and condition B without departing from the scope of the present disclosure. In other words, as used herein, the phrase “based on” shall be construed in the same manner as the phrase “based at least in part on” or the phrase “based at least partially on.”

From the foregoing, it will also be appreciated that various modifications can be made without deviating from the disclosure or the technology. For example, one of ordinary skill in the art will understand that various components of the technology can be further divided into subcomponents, or that various components and functions of the technology can be combined and integrated. In addition, certain aspects of the technology described in the context of particular embodiments can also be combined or eliminated in other embodiments. Furthermore, although advantages associated with certain embodiments of the technology have been described in the context of those embodiments, other embodiments can also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A method for aligning semiconductor devices, the method comprising:
inducing an electrical current in a placement device using magnetic features disposed in or on a first semiconductor device;
capturing measurements of the induced electrical current;
identifying locations of the magnetic features along the first semiconductor device based at least in part on the captured measurements; and
aligning the first semiconductor device with a second semiconductor device based at least in part on the identified locations of the magnetic features.

2. The method of claim 1, wherein inducing the electrical current comprises moving the placement device relative to the first semiconductor device.

3. The method of claim 2, wherein moving the placement device comprises moving electrical pads of the placement device laterally, vertically, and/or rotationally relative to the first semiconductor device.

4. The method of claim 1, wherein capturing measurements of the induced electrical current comprises capturing the measurements using a galvanometer coupled to electrical pads of the placement device.

5. The method of claim 4, wherein identifying locations of the magnetic features comprises analyzing the measurements to determine positions where the induced electrical current is maximized.

6. The method of claim 1, further comprising monitoring the captured measurements during bonding of the first and second semiconductor devices to maintain alignment.

7. The method of claim 6, wherein monitoring the captured measurements comprises making real-time adjustments to the alignment of the first and second semiconductor devices based on changes in the captured measurements.

8. A stack of semiconductor devices, the stack comprising:
a first semiconductor device having a first magnetic feature disposed in or on the first semiconductor device; and
a second semiconductor device vertically aligned with the first semiconductor device and having a second magnetic feature disposed in or on the second semiconductor device,
wherein the first magnetic feature is vertically aligned with the second magnetic feature.

9. The stack of claim 8, wherein the first magnetic feature is embedded within the first semiconductor device.

10. The stack of claim 9, wherein the first magnetic feature is disposed within the first semiconductor device such that the first magnetic feature is not visible on an exterior of the first semiconductor device.

11. The stack of claim 8, wherein the first magnetic feature is positioned at an edge of the first semiconductor device.

12. The stack of claim 8, wherein the first magnetic feature and/or the second magnetic feature comprise cobalt, neodymium iron boron, ferrite, samarium cobalt, and/or a magnetic fluid in stable nano-colloids.

13. The stack of claim 8, wherein the second semiconductor device further comprises a third magnetic feature that is not vertically aligned within any magnetic feature disposed in or on the first semiconductor device.

14. The stack of claim 8, wherein the first semiconductor device is bonded to the second semiconductor device.

15. An alignment system, comprising:
a placement device including—
a chuck configured to hold or manipulate a first semiconductor device;
a plurality of electrical pads disposed in or on the chuck; and
at least one galvanometer coupled to the plurality of electrical pads,
wherein the placement device is usable to—
move the first semiconductor device relative to a second semiconductor device such that a magnetic field of a first magnetic feature disposed in or on the first semiconductor device and/or a magnetic field of a second magnetic feature disposed in or on the second semiconductor device induce electrical currents in electrical pads of the plurality of electrical pads, and
align the first semiconductor device with the second semiconductor device based at least in part on measurements of the induced electrical currents captured by the at least one galvanometer.

16. The alignment system of claim 15, wherein at least one electrical pad of the plurality of electrical pads is formed of copper.

17. The alignment system of claim 15, wherein the at least one galvanometer includes a first galvanometer, and wherein at least two electrical pads of the plurality of electrical pads are coupled to the first galvanometer.

18. The alignment system of claim 17, wherein the at least two electrical pads are coupled to one another to form a loop or coil.

19. The alignment system of claim 17, wherein the at least one galvanometer further includes a second galvanometer, wherein two or more electrical pads of the plurality of electrical pads are coupled to the second galvanometer, and wherein the two or more electrical pads are different from the at least two electrical pads.

20. The alignment system of claim 17, wherein the placement device is further useable to—
move the chuck and the at least two electrical pads relative to the first semiconductor device such that the magnetic field of the first magnetic feature induces first electrical currents in the at least two electrical pads; and
align the first magnetic feature with one or more of the at least two electrical pads based at least in part on measurements of the induced first electrical currents captured by the first galvanometer.
